(19) United States
(12) Patent Application Publication
(10) Pub. No.: US 2024/0141488 A1
(43) Pub. Date: May 2, 2024

(54) COATED SUBSTRATE SUPPORT ASSEMBLY FOR SUBSTRATE PROCESSING IN PROCESSING CHAMBERS

(71) Applicant: Applied Materials, Inc., Santa Clara, CA (US)

(72) Inventors: David JORGENSEN, Mountain View, CA (US); Songjae LEE, San Jose, CA (US); Hao WANG, Livermore, CA (US); Yi-Chiau HUANG, Fremont, CA (US); Christopher BEAUDRY, Santa Clara, CA (US)

(21) Appl. No.: 18/050,375

(22) Filed: Oct. 27, 2022

(51) Int. Cl. C23C 16/455; C23C 16/08; C23C 18/16; C23C 18/32; C23C 28/00; H01L 21/687

(52) U.S. Cl. CPC C23C 16/45527; C23C 16/08; C23C 18/165; C23C 18/32; C23C 28/3455; H01L 21/68757

(57) ABSTRACT

Embodiments of the present disclosure generally relate to a substrate support having a surface coating which reduces defect formation and back side metal contamination during substrate processing. A support body includes a body having an outer surface and a surface coating formed from a non-metal or a reduced-metal material disposed over at least a top surface of the outer surface of the body. In an embodiment, the surface coating includes a two-part coating having an optional first coating layer formed over an entire outer surface of the support body.

### BACKGROUND

### Field

Embodiments of the present disclosure generally relate to an apparatus for supporting a substrate during processing in an electronic device fabrication process. More particularly, embodiments disclosed herein relate to a substrate support having a surface coating which reduces defect formation and back side metal contamination during substrate processing, and methods of forming the coating.

### Description of the Related Art

Integrated circuits are formed in and on silicon and other semiconductor substrates. In the case of single crystal silicon, substrates are made by growing an ingot from a bath of molten silicon, and then sawing the solidified ingot into multiple substrates. An epitaxial silicon layer may then be formed on the monocrystalline silicon substrate to form a defect free silicon layer that may be doped or undoped. Semiconductor devices, such as transistors, may be manufactured from the epitaxial silicon layer. The electrical properties of the formed epitaxial silicon layer are generally better than the properties of the monocrystalline silicon substrate.

Surfaces of the monocrystalline silicon and the epitaxial silicon layer are susceptible to contamination when exposed to typical substrate fabrication facility ambient conditions. For example, a native oxide layer may form on the monocrystalline silicon surface prior to deposition of the epitaxial layer due to handling of the substrates and/or exposure to ambient environment in the substrate processing facility. Additionally, foreign contaminants such as carbon and oxygen species present in the ambient environment may deposit on the monocrystalline surface. The presence of an oxide layer or contaminants on the monocrystalline silicon surface negatively affects the quality of an epitaxial layer subsequently formed on the monocrystalline surface. Therefore, a precleaning process may be performed to remove an oxide layer or contaminants from the monocrystalline surface. However, conventional preclean processes involve exposure of the substrate to process gases which may cause surface corrosion of the substrate support. In some examples, material byproducts resulting from corrosion of the substrate support may contact the substrate causing defect formation and back side metal contamination on the substrate.

Therefore, there is a need in the art to provide an improved substrate support which resists the corrosive effects of preclean process gases that minimizes substrate defect formation and back side metal contamination.

### SUMMARY

The present disclosure describes a support body for supporting a substrate in a processing chamber and methods for forming a surface coating on the support body. In some embodiments, a method of forming a surface coating on a support body of a processing chamber includes depositing a first material over an outer surface of the support body, thereby forming a first coating layer, the first material including at least one of a metal-containing material or alloy. The method includes depositing a second material over at least a portion of the first coating layer disposed over the top surface of the support body, thereby forming a second coating layer, wherein the second material is a non-metal or a reduced-metal material.

In some embodiments, a support body includes a body having an outer surface with the outer surface of the body including a top surface. The support body also includes a two-part coating disposed over the outer surface of the body. The two-part coating includes a first coating layer disposed over an entirety of the outer surface of the body. The first coating layer including at least one of a metal-containing material or alloy. The two-part coating includes a second coating layer disposed over the first coating layer. The second coating layer is disposed over at least a portion of the first coating layer disposed over the top surface of the body and extends a radial distance from a center of the body. The second coating layer is a non-metal or reduced-metal coating.

In another embodiment, a support body includes a body formed from a material resistant to the process environment of a processing chamber and having an outer surface including a top surface. The support body also includes a coating disposed over the outer surface of the body. The coating is disposed over at least a portion of the top surface of the body and extends a radial distance from a center of the body. The coating layer is a non-metal or reduced-metal coating.

In some embodiments, a system includes a processing chamber configured to clean a substrate. The processing chamber includes a chamber body, a lid assembly disposed at an upper end of the chamber body, and a substrate support assembly at least partially disposed within the chamber body and configured to support the substrate in the processing chamber. The lid assembly includes a dual channel showerhead having a first set of channels providing fluid communication above and below a plane of the showerhead and a second set of channels providing fluid communication with a side port of the chamber body. The substrate support assembly includes a support body having an upper surface, the upper surface extending a first radial distance from a center of the support body. The substrate support assembly includes a stem coupled to the support body and a coating disposed over the support body. The coating includes a first coating layer disposed over an entirety of the outer surface of the support body. The coating includes a second coating layer disposed over the first coating layer, the second coating layer the second coating layer extending over at least the substrate supporting surface of the support body, and the second coating layer being a non-metal or reduced-metal coating.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1A is a cross-sectional view of a processing chamber, according to certain embodiments.

FIG. 1B is an isolated, isometric view of a support body of a substrate support assembly of FIG. 1A, according to certain embodiments.

FIG. 1C is an enlarged cross-sectional view of a portion of the stem of FIG. 1A illustrating an exemplary surface coating disposed thereon, according to certain embodiments.

FIGS. 1D and 1E are enlarged cross-sectional views of a portion of the support body of FIG. 1B illustrating exemplary surface coatings disposed thereon, according to certain embodiments.

FIG. 2 is a diagram illustrating a method of forming the exemplary surface coating of FIG. 1C, according to certain embodiments.

FIG. 3 is a diagram illustrating a method of forming the exemplary surface coating of FIG. 1D, according to certain embodiments.

FIG. 4 is a diagram illustrating a method of forming the exemplary surface coating of FIG. 1D via ENP and EBIAD processes, according to certain embodiments.

FIG. 5 is a diagram illustrating a method of forming the exemplary surface coating of FIG. 1D via ENP and ALD processes, according to certain embodiments.

FIG. 6 is a diagram illustrating a method of forming the exemplary surface coating of FIG. 1D via ALD processing, according to certain embodiments.

FIG. 7 is a diagram illustrating a method of forming the exemplary surface coating of FIG. 1E, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein relate to a substrate support having a two-part surface coating which reduces defect formation and back side metal contamination during substrate processing, and methods of forming the coating.

Certain embodiments disclosed herein provide a substrate support assembly (also referred to as a “pedestal”) having a nonmetal or reduced metal surface coating, in contrast to conventional coatings containing metals. In an embodiment, an optional first coating, which is able to fill even the smallest feature sizes and intricate structures, is applied to the entire substrate support assembly to reduce overall surface corrosion of the substrate support assembly. A second coating, which is free of or contains a reduced atomic percentage of metal contaminants, is applied to at least a top portion of the substrate support assembly (e.g., support body) to reduce substrate back side metal contamination. In some embodiments, the optional first coating may be omitted and the second coating may therefore be applied directly on the substrate support. Thus, the coating performance is improved compared to conventional coatings containing metal contaminants.

In some examples, a substrate may include a silicon-containing material, and the surface may include a material, such as silicon (Si), germanium (Ge) or silicon germanium alloys (SiGe). In some examples, the Si, Ge, or SiGe surface may have an oxide layer, such as a native oxide layer, and contaminants disposed thereon.

Due to the sensitivity of epitaxial deposition processes to oxides and contaminants, such as carbon-containing contaminants, surface contamination resulting from exposure to cleanroom environments for a few hours can become significant enough for the accumulated oxides and contaminants to affect the quality of a subsequently formed epitaxial layer. Therefore, a precleaning process may be performed to remove an oxide layer or contaminants from the surface. As used herein, the term “precleaning” refers to a process involving exposure of a substrate (e.g., a semiconductor substrate) to one or more process gases to remove an oxide layer or contaminants from the substrate surface. Herein, “precleaning” may also be referred to as “etching” or “selective etching.”

In some examples, the substrate surface may be cleaned by performing an oxide removal process and a contaminant removal process. In one example, the oxides may be removed from the surface of the substrate using a precleaning process, and the contaminants, such as carbon-containing contaminants, may be removed from the surface of the substrate using a reducing process.

In some examples, the process gas may include a reactive gas such as a fluorine- or chlorine-containing gas. In some examples, the process gas may further include a vapor. In some examples, the process gas may further include one or more purge gases or carrier gases (e.g., hydrogen, helium, and/or argon). In some examples, the reactive gas may include hydrogen fluoride (e.g., HF), anhydrous hydrogen fluoride (which may be referred to as “AHF”), diatomic fluorine (F₂), nitrogen fluoride (e.g., nitrogen trifluoride (NF₃)), carbon fluoride (e.g., carbon tetrafluoride (CF₄), hexafluoroethane (C₂F₆), trifluoromethane (CHF₃), difluoromethane (CH₂F₂), octofluoropropane (C₃F₈), octofluorocyclobutane (C₄F₈), octofluoro[1-]butane (C₄F₈), octofluoro[2-]butane (C₄F₈), or octofluoroisobutylene (C₄F₈)), sulfur fluoride (e.g., sulfur hexafluoride (SF₆)), ammonia (NH₃), or combinations thereof.

In some examples, a flow rate of the reactive gas may be about 50 sccm to about 500 sccm for a 300 mm substrate. In some examples, a concentration of the reactive gas within the processing chamber (e.g., in contact with the substrate surface) may be about 5% wt/wt to about 75% wt/wt of the total process gas mixture including any other components (e.g., vapor, carrier or purge gases).

In some examples, a vapor may include water (e.g., distilled water), a primary alcohol (e.g., methyl alcohol, ethyl alcohol, propyl alcohol, butyl alcohol, or isobutyl alcohol), a secondary alcohol (e.g., isopropyl alcohol or sec-butyl alcohol), a tertiary alcohol (e.g., tert-butyl alcohol), a cyclic alcohol (e.g., cyclohexyl alcohol), a complex alcohol (e.g., 4-ethyl-3-hexanol), a C1 alcohol, a C2 alcohol, a C3 alcohol, a C1-C2 alcohol, a C1-C3 alcohol, a C1-C4 alcohol, an organic acid, or combinations thereof. In some examples, the vapor may increase a rate of reaction between the reactive gas and surface oxides. In some examples, lower carbon number alcohols may increase the reaction rate to a greater degree compared to higher carbon number alcohols (e.g., a relative rate of reaction may be C1 alcohol>C2 alcohol>C3 alcohol). In some examples, a flow rate of the vapor may be about 5 sccm to about 500 sccm for a 300 mm substrate. In some examples, a flow ratio of the reactive gas to the vapor may be about 10:1 to about 1:10. In some examples, a concentration of the vapor may be about 5 wt/wt to about 75 wt/wt of the total process gas mixture including any other components (e.g., reactive, carrier or purge gases).

In operation, the reactive gas and vapor may be provided to the process chamber through different pathways (i.e., separately) and mixed after arrival to the process chamber and before contacting the substrate. In some other examples, the reactive gas may be mixed with the vapor for charging to the process chamber. Mixing of the gases may be spatially separated from a processing region in which the substrate is disposed. The term “spatially separated” described herein may refer to a mixing region that is separated from a substrate processing region by one or more chamber components, or even a conduit between a mixing chamber and a substrate processing chamber. In some examples, a processing temperature, which may refer to a temperature of the mixed process gas within the processing chamber (e.g., a temperature of the mixed process gas in contact with the substrate surface), may be about 0° C. or less, such as about −50° C. to about 40° C. In some examples a pressure in the processing chamber may be within a range of about 0.5 Torr to about 20 Torr.

The preclean process may be largely conformal and selective for oxide layers, and thus does not readily etch silicon (e.g., low-k spacers or other dielectric materials), germanium, or nitride layers regardless of whether the layers are amorphous, crystalline or polycrystalline. In some examples, selectivity of the process gas for oxide compared to silicon or germanium may be at least about 3:1, such as about 5:1 or greater, such as about 10:1 or greater. The process gas may also be highly selective of oxide compared to nitride. In some examples, the selectivity of the process gas for oxide compared to nitride may be at least about 3:1, such as about 5:1 or greater, such as about 10:1 or greater, such as about 20:1 or greater, such as about 50:1 or greater, such as about 80:1 or greater, such as about 100:1 or greater, such as about 120:1 or greater.

In some examples, either during the preclean process or after performing the preclean process, thermal energy may be applied to the processed substrate to help remove any generated byproducts. In some examples, the thermal energy may be provided via a radiant, convective and/or conductive heat transfer process that causes the unwanted byproducts found on the substrate surface to sublimate.

In some examples, an additional process may be performed to remove carbon contaminants or other contaminants from the surface of the substrate. In some examples, contaminant removal may occur before or after the precleaning process. In some examples, contaminant removal may include a plasma process performed in a plasma-cleaning chamber. The plasma process may use a plasma formed from a gas including hydrogen (H₂), helium (He), ammonia (NH₃), a fluorine-containing gas, or a combination thereof. The plasma may be inductively or capacitively coupled, the plasma may be formed by a microwave source in a processing chamber, or the plasma may be formed by a remote plasma source.

In some examples, an epitaxial layer may be formed on the surface of the substrate. If cleaned prior, as described above, the surface of the substrate is uniformly oxide and contaminant free which improves the quality of layers subsequently formed on the surface of the substrate. An exemplary processing chamber that can be used to perform the epitaxial deposition process is the Centura™ Epi chamber, which is available from Applied Materials, Inc., of Santa Clara, California. Chambers from other manufacturers may also be used.

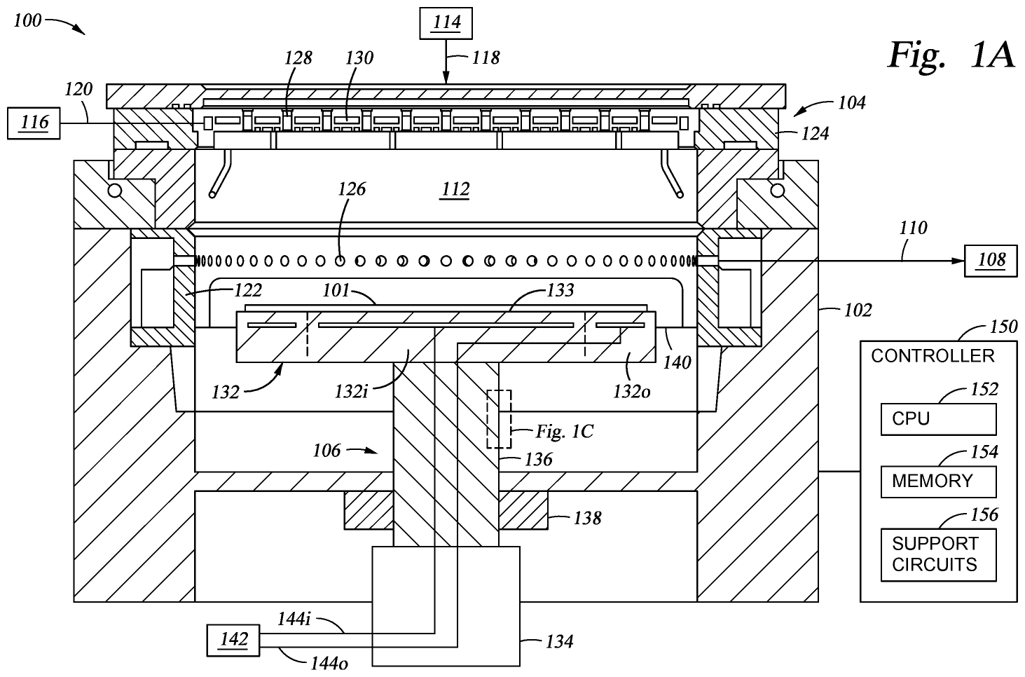

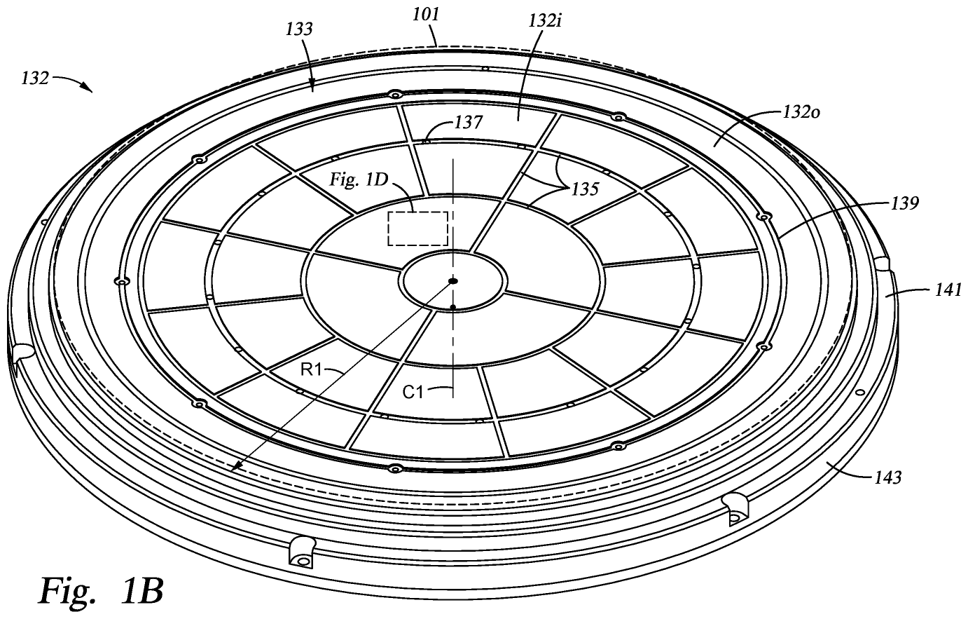

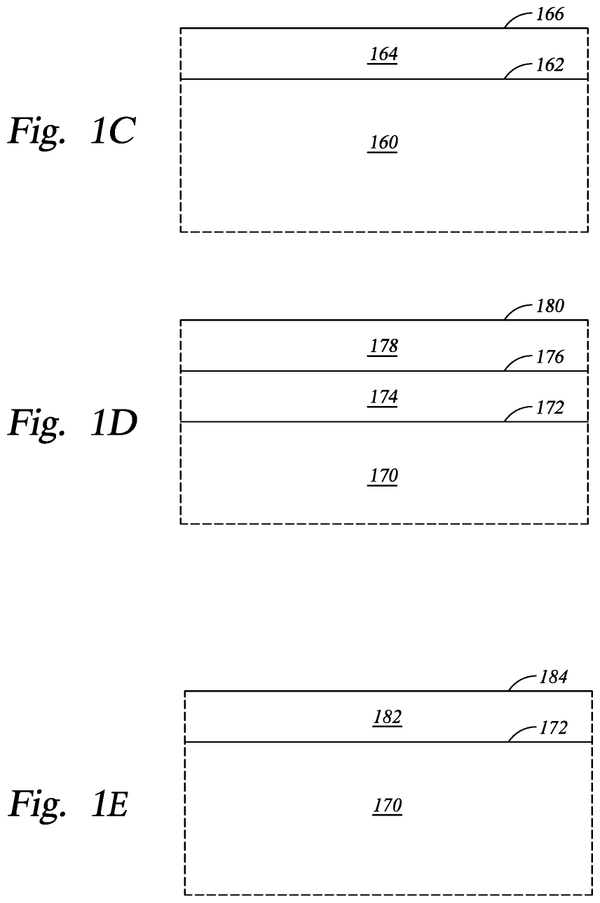

FIG. 1A is a cross-sectional view of a processing chamber 100, according to certain embodiments. The processing chamber 100 is configured to perform a precleaning process. In one example, the processing chamber 100 may be a Siconi™ or Selectra™ chamber, which are available from Applied Materials, Santa Clara, California. The processing chamber 100 generally includes a chamber body 102, a lid assembly 104, and a substrate support assembly 106. The lid assembly 104 is disposed at an upper end of the chamber body 102, and the substrate support assembly 106 is at least partially disposed within the chamber body 102. A vacuum system is used to remove gases from the processing chamber 100. The vacuum system includes a vacuum pump 108 coupled to a vacuum port 110 disposed in the chamber body 102. A pumping ring 122 is disposed within the chamber body 102. The pumping ring 122 has a plurality of exhaust ports 126 providing fluid communication between the inside of the processing chamber 100 and the vacuum port 110 for exhausting gas therethrough.

The lid assembly 104 includes a plurality of stacked components configured to provide gases to a processing region 112 within the chamber 100. The lid assembly 104 is connected to a first gas source 114 and a second gas source 116. Gases from the first gas source 114 are introduced to the lid assembly 104 through a top port 118. Gases from the second gas source 116 are introduced to the lid assembly 104 through a side port 120. In some examples, the first gas source 114 may provide at least a first part of a process gas (e.g., a reactive gas). In some examples, the second gas source 116 may provide a second part of the process gas (e.g., a vapor). In some examples, one or more purge gases or carrier gases may also be delivered to the processing region 112 from the first gas source 114, second gas source 116, or from another gas source.

The lid assembly 104 generally includes a showerhead 124 disposed above the processing region 112 through which gases from the first gas source 114 are introduced to the processing region 112. The showerhead 124 may include one or more additional plates (e.g., blocker plate, faceplate) disposed above the plate shown in FIG. 1A. Each plate of the showerhead 124 may include multiple apertures formed therethrough which connect gas regions above and below each respective plate. In some examples, the showerhead 124 may be heated. In some examples, gases may be mixed in or above the showerhead 124 during heating. In one example, the showerhead 124 may be heated to about 190° C. while a substrate to be processed is at about 10° C.

In the example illustrated in FIG. 1A, the showerhead 124 is a dual channel showerhead which has a first set of channels 128 and a second set of channels 130. The first set of channels 128 provides fluid communication above and below a plane of the showerhead 124 for gases from the top port 118 to enter the processing region 112. The second set of channels 130 provides fluid communication with the side port 120 for gases from the second gas source 116 to enter the processing region 112. The dual channel showerhead may be particularly advantageous to improve mixing of different gases coming from the first gas source 114 and second gas source 116.

The substrate support assembly 106 (also referred to as a “pedestal”) includes a support body 132 (also referred to as a “puck”) to support a substrate 101 thereon during processing and a stem 136 coupled to the support body 132. The substrate support assembly 106 includes a surface coating which is described in more detail below with respect to FIGS. 1C— 1E. In some examples, the support body 132 may be modular and thus easily replaced with another coated part. Thus, replacement of the entire substrate support assembly 106 may be avoided when only the coating on the support body 132 is damaged.

The support body 132 includes a top surface having a flat, or a substantially flat, substrate-supporting surface 133 (also referred to as a “substrate-supporting area” or “substrate contact surface” of the support body 132). Referring to FIG. 1B, the substrate-supporting surface 133 is the region underlying and/or in contact with the substrate 101 (shown in phantom in FIG. 1B). In some examples, the substrate-supporting surface 133 may extend a radial distance R1 from a center C1 of the support body 132. Although as shown in FIG. 1B, an outer perimeter of the substrate 101 matches the size of the substrate-supporting surface 133, in some examples, the substrate 101 may overhang the substrate-supporting surface 133. The substrate-supporting surface 133 includes multiple surface features (such as channels 135, ports 137, and recess 139 shown in FIG. 1B) formed therein which, due to their small dimensions and/or intricate structures, may be difficult to coat using conventional one-part coatings. Advantageously, in an embodiment, a two-part coating described herein can cover substantially an entire outer surface of each surface feature and, thus protect from corrosion, even the smallest feature sizes. In some examples, the two-part coatings may be capable of filling feature sizes having a critical dimension of about 30 μm or less. Advantageously, two-part coatings described herein are capable of filling high aspect ratio features with aspect ratios of about 5:1 or greater, such as about 10:1 or greater, such as about 20:1 or greater, which improves protection of high aspect ratio features from corrosion.

As shown in FIG. 1A, the support body 132 includes two independent temperature control zones (referred to as “dual zone”) to control substrate temperature for center-to-edge processing uniformity and tuning. In the example illustrated in FIG. 1A, the support body 132 has an inner zone 132i and an outer zone 132o surrounding the inner zone 132i. As shown in FIG. 1B, the inner zone 132i and outer zone 132o are separated from each other in the radial direction by circumferential recess 139. In some other examples, the support body 132 may have more than two independent temperature control zones (referred to as “multi zone”).

The support body 132 is coupled to an actuator 134 by the stem 136 which extends through a centrally-located opening formed in a bottom of the chamber body 102. The actuator 134 is flexibly sealed to the chamber body 102 by bellows 138 that prevent vacuum leakage around the stem 136. The actuator 134 allows the support body 132 to be moved vertically within the chamber body 102 between a processing position and a loading position. The loading position is slightly below a substrate opening 140 formed in a sidewall of the chamber body 102.

The processing chamber 100 also includes an ultra-low temperature kit 142 for lowering a temperature of the substrate to be processed, which can improve selectivity for oxide removal (e.g., native oxide removal) compared to other materials, such as low-k dielectric materials and silicon nitride (e.g., SiN), among others. In some examples, the temperature of the substrate to be processed and/or a temperate of the support body 132 may be lowered to about −30° C. to about 10° C. The ultra-low temperature kit 142 provides a continuous flow of ultra-low temperature coolant to the support body 132 which cools the support body 132 to a desired temperature. In some examples, the ultra-low temperature coolant may include perfluorinated, inert polyether fluids (e.g., Galden® fluids). In the example illustrated in FIG. 1A, the ultra-low temperature coolant is provided to the inner zone 132i and outer zone 132o of the support body 132 through inner coolant channel 144i and outer coolant channel 144o, respectively. The coolant channels are drawn schematically in FIG. 1A and may have a different arrangement from what is shown. For example, each coolant channel may be in the form of a loop.

A system controller 150, such as a programmable computer, is coupled to the processing chamber 100 for controlling the processing chamber 100 or components thereof. For example, the system controller 150 may control the operation of the processing chamber 100 using a direct control of the substrate support assembly 106, vacuum pump 108, first gas source 114, second gas source 116, actuator 134, and/or ultra-low temperature kit 142 or using indirect control of other controllers associated therewith. In operation, the system controller 150 enables data collection and feedback from the respective components to coordinate processing in the processing chamber 100.

The system controller 150 includes a programmable central processing unit (CPU) 152, which is operable with a memory 154 (e.g., non-volatile memory) and support circuits 156. The support circuits 156 are conventionally coupled to the CPU 152 and comprise cache, clock circuits, input/output subsystems, power supplies, and the like, and combinations thereof coupled to the various components of the processing chamber 100.

In some embodiments, the CPU 152 is one of any form of general purpose computer processor used in an industrial setting, such as a programmable logic controller (PLC), for controlling various monitoring system component and sub-processors. The memory 154, coupled to the CPU 152, is non-transitory and is typically one or more of readily available memory such as random access memory (RAM), read only memory (ROM), floppy disk drive, hard disk, or any other form of digital storage, local or remote.

Herein, the memory 154 is in the form of a computer-readable storage media containing instructions (e.g., non-volatile memory), that when executed by the CPU 152, facilitates the operation of the processing chamber 100. The instructions in the memory 154 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

FIG. 1C is an enlarged cross-sectional view of a portion of the stem 136 of FIG. 1A illustrating an exemplary surface coating disposed thereon, according to certain embodiments. The stem 136 includes a base layer 160 having an outer surface 162. The “outer surface” may refer to a surface which is exposed before the surface coating is disposed thereon. In an embodiment, the stem 136 includes a first coating layer 164 disposed over the outer surface 162. The first coating layer 164 has an outer surface 166. As shown, the first coating layer 164 is in direct contact with the outer surface 162. However, in some other examples, one or more additional layers may be disposed between the base layer 160 and the first coating layer 164. Although only a portion of the stem 136 is shown in FIG. 1C, in some examples, the first coating layer 164 may be disposed over an entirety of the substrate support assembly 106 including corresponding outer surfaces of each of the stem 136 and the support body 132. In some examples and as further described below, the first coating layer 164 may be disposed over an entirety of the support body 132 or over one or more individual surfaces or portions of the support body 132. For example, the first coating layer 164 may be disposed over one or more surfaces of support body 132 (shown in FIG. 1B) such as over the substrate-supporting surface 133, over an area of the support body 132 outside the substrate-supporting surface 133 (e.g., over an upward-facing surface 141 surrounding the substrate-supporting surface 133 or around a side 143 of the support body 132), or combinations thereof. In some examples, the first coating layer 164 may be disposed over an entirety of the upper surface of the support body 132, which includes the substrate-supporting surface 133 and the upward-facing surface 141.

In some examples, the base layer 160 may include a metal such as aluminum, nickel (e.g., Ni100 or Ni200), nickel alloy (e.g., C22, IN625, C276), or other metal alloys, a ceramic such as aluminum nitride or aluminum oxide, mild steel alloys, stainless steel alloys, or combinations thereof.

In some examples, the first coating layer 164 may include a metal-containing material or alloy. In one example, the first coating layer 164 includes a nickel and phosphorus alloy formed through electroless nickel plating (ENP). In some examples, the ENP coating may be either a high-phosphate or low-phosphate ENP. In some examples, a thickness of the ENP coating may be about 10 μm to about 50 μm, such as about 10 μm to about 20 μm, about 20 μm to about 30 μm, about 30 μm to about 40 μm, or about 40 μm to about 50 μm. In one example, a thickness of the ENP coating may be about 25 μm. In some other examples, the first coating layer 164 may include an electrolytic nickel plating.

In an embodiment, the first coating layer 164 on the stem 136 may be omitted if the stem 136 including the base layer 160 is formed from material resistant to the process environment. In some examples, if the base layer 160 of the stem 136 includes a metal such as nickel or nickel alloy, forming the first coating layer 164 on the stem 136 may be omitted.

In some other examples, the first coating layer 164 may be deposited using atomic layer deposition (ALD). In some examples, the first coating layer 164 may include nickel, a precious metal (e.g., platinum or gold), aluminum oxide (e.g., Al₂O₃), yttrium oxide (e.g., Y₂O₃), yttrium oxyfluoride (e.g., YOF), yttrium fluoride (e.g., YF₃), nickel fluoride (e.g., NiF2), magnesium fluoride (e.g., MgF₂), silicon dioxide (e.g., SiO₂), or combinations thereof. In some examples, a thickness of the first coating layer 164 deposited using ALD may be about 5 nm to about 300 nm, such as about 5 nm to about 75 nm, about 75 nm to about 150 nm, about 150 nm to about 225 nm, or about 225 nm to about 300 nm. In one example, a thickness of the first coating layer 164 deposited using ALD may be about 50 nm.

In some examples, the first coating layer 164 may be a conformal layer, which may generally conform to the contours of the base layer 160. The term “conformal” may refer to a coating which has a thickness within +/−5% of the nominal coating thickness. In some examples, the first coating layer 164 may have about equal thickness over the entire outer surface 162. In some examples, during application the first coating layer 164 may have a flowability parameter which enables the coating to fill even the smallest features formed in the outer surface 162. For example, the first coating layer 164 may be capable of filling feature sizes having a critical dimension within a range of about 30 μm to about 50 μm.

In some examples, a thickness of the first coating layer 164 may be within a range of about 0.1 μm to about 50 μm or from about 5 nm to about 300 nm. In some examples, a surface roughness average (Ra) of the first coating layer 164 may be within a range of about 2 pinches (pin) to about 64 pin, such as about 20 pin. In some examples, the first coating layer 164 may be resistant to exposure with 50 mol % liquid hydrochloric acid (HCl) for at least 24 hours without pitting or discoloration. In some examples, the first coating layer 164 may be resistant to HCl vapor for at least 22 days without pitting or discoloration.

FIGS. 1D and 1E are enlarged cross-sectional views of a portion of the support body 132 of FIG. 1B illustrating exemplary surface coatings disposed thereon, according to certain embodiments. The support body 132 includes a base layer 170 having an outer surface 172. In an embodiment, as shown in FIG. 1D, the support body 132 may have an optional first coating layer 174 disposed over the outer surface 172. The first coating layer 174 has an outer surface 176. As shown, the first coating layer 174 is in direct contact with the outer surface 172. However, in some other examples, one or more additional layers may be disposed between the base layer 170 and first coating layer 174.

In some examples, the base layer 170 may include a metal such as aluminum, stainless steel, nickel, nickel alloy, or other metal alloys, a ceramic such as aluminum nitride or aluminum oxide, or combinations thereof. In some examples, the base layer 170 may be formed from the same material as the base layer 160. In some examples, the support body 132 may be formed from a bulk of metal containing material such that the material used for forming the base layer 170 may be the same material for forming the support body 132.

In some examples, the optional first coating layer 174 may include one or more aspects of the first coating layer 164 described above. In some examples, the first coating layer 174 may be the same as the first coating layer 164 of FIG. 1C. In some examples, the first coating layer 174 may include nickel, a precious metal (e.g., platinum or gold), aluminum oxide (e.g., Al₂O₃), yttrium oxide (e.g., Y₂O₃), yttrium oxyfluoride (e.g., YOF), yttrium fluoride (e.g., YF₃), nickel fluoride (e.g., NiF2), magnesium fluoride (e.g., MgF₂), silicon dioxide (e.g., SiO₂), or combinations thereof. Although not shown in FIG. 1D, the first coating layer 174 may cover substantially an entire outer surface 172 of each surface feature (such as channels 135, ports 137, and recess 139 shown in FIG. 1B) formed in a substrate-supporting area of the base layer 170. In an embodiment, when the first coating layer 174 is deposited using ENP or ALD, the first coating layer 174 may be deposited over the entire outer surface 172 of the base layer 170 of the support body 132.

In an embodiment, the support body 132 includes a second coating layer 178 disposed over the outer surface 176 of the first coating layer 174. The second coating layer 178 has an outer surface 180. As shown, the second coating layer 178 is in direct contact with the outer surface 176. However, in some other examples, one or more additional layers may be disposed between the first coating layer 174 and second coating layer 178.

In one example, as shown in FIG. 1D, the support body 132 may be formed in which both the optional first coating layer 174 and the second coating layer 178 are disposed over the support body 132. In one embodiment, the second coating layer 178 may be formed over the entirety of the outer surface 176 of the first coating layer 174. In another embodiment, the second coating layer 178 may be formed over just a portion of the first coating layer 174 disposed over the substrate-support surface 133 of the support body 132.

In another example, as shown in FIG. 1E, the support body 132 may be formed in which the optional first coating layer 174 is omitted and the second coating layer 178 is instead disposed directly over the base layer 170 of the support body 132. In such examples and as further described below, the first coating layer 174 is not needed when the support body 132 is formed from a material which is resistant to the process environment. Instead, the second coating layer 178 is in direct contact with the outer surface 172 of the base layer 170. In some other examples, one or more additional layers may be disposed between the base layer 170 and second coating layer 178.

The portion of the support body 132 shown in FIGS. 1D and 1E correspond to the substrate-supporting surface 133. However, in some examples, the second coating layer 178 may be applied on areas outside the substrate-supporting surface 133 as described above with respect to FIG. 1D.

In some examples, the second coating layer 178 may include a material which is free of metal contaminants (also referred to as “non-metal” or “metal-free”). In some examples, non-metal materials may include materials having a metal concentration of about 2000 ppm or less. In another example, the second coating layer 178 may include a material containing a reduced atomic percentage of metal contaminates (also referred to as “reduced-metal”), such as between a range of about 10 atomic (at.) % to about 50 at. %. In some examples, the second coating layer 178 may be deposited using chemical vapor deposition (CVD), plasma enhanced CVD (PECVD), atomic layer deposition (ALD), plasma enhanced ALD (PEALD), electron beam ion assisted deposition (EBIAD), magnetron sputtering (MS), thermal evaporation, cathodic arc deposition, or air plasma spray. In an embodiment, when the second coating layer 178 is deposited using ALD, the second coating layer 178 may be deposited over the entire outer surface of the preceding layer beneath it. In some examples, the second coating layer 178 may be an amorphous film.

In some other examples, the second coating layer 178 may be or include yttrium oxyfluoride (YOF). In some examples, the YOF coating may entirely cover the underlying surface. In some examples, an individual concentration of yttrium atoms, oxygen atoms, and fluoride atoms in the YOF coating may be within a range of about 10 atomic (at.) % to about 50 at. %. In one example, the concentration of the Y component may be about equal (i.e., about 33 at. % of Y atoms, 33 at. % of 0 atoms, and 33 at. % of F atoms). In general, YOF coatings described above are more resistant to etching (e.g., when exposed to AHF/water process chemistry) compared to other coatings such as silicon carbide. In some examples using 4 wt % to 25 wt % HF in liquid water, an etch rate of the YOF coatings may be less than about 0.5 Angstroms/minute (A/min). In some other examples, in an application specific process environment (e.g., using the processing chamber 100 described above with HF and water vapor at temperatures less than about 0° C.), an etch rate of the YOF coatings may be less than about 0.15 Å/min.

In some other examples, the second coating layer 178 may be or include yttrium fluoride (YF₃). In some examples, a thickness of the YF₃ coating may be about 100 nm to about 500 nm, such as about 100 nm to about 200 nm, about 200 nm to about 300 nm, about 300 nm to about 400 nm, or about 400 nm to about 500 nm. In other examples, a thickness of the YF₃ coating may be about 1 μm to about 11 μm, such as about 1 to about 3 μm, about 3 to about 5 μm, about 5 μm to about 7 μm, about 7 μm to about 9 μm, or about 9 μm to about 11 μm. In some examples, the YF₃ coating may entirely cover the underlying surface. In some examples, an individual concentration of yttrium atom and fluoride atoms in the YF₃ coating may be within a range of about 10 atomic (at.) % to about 80 at. %. In one example, the concentration of each component may be about 25 at. % of Y atoms and 75 at. % of F atoms. In general, YF₃ coatings described above are more resistant to etching (e.g., when exposed to AHF/water process chemistry) compared to other coatings such as silicon carbide. In some examples using 4 wt % to 25 wt % HF in liquid water, an etch rate of the YF₃ coatings may be less than about 0.5 Angstroms/minute (A/min). In some other examples, in an application specific process environment (e.g., using the processing chamber 100 described above with HF and water vapor at temperatures less than about 0° C.), an etch rate of the YF₃ coatings may be less than about 0.15 Å/min.

In some other examples, the second coating layer 178 may be or include yttrium oxide (Y₂O₃). In some examples, a thickness of the Y₂O₃ coating may be about 100 nm to about 500 nm, such as about 100 nm to about 200 nm, about 200 nm to about 300 nm, about 300 nm to about 400 nm, or about 400 nm to about 500 nm. In some examples, the Y₂O₃ coating may entirely cover the underlying surface. In some examples, an individual concentration of yttrium atoms and oxygen atoms in the Y₂O₃ coating may be within a range of about 10 atomic (at.) % to about 70 at. %. In one example, the concentration of each component may be about 40 at. % of Y atoms and 60 at. % of O.

In some examples, the second coating layer 178 described above being formed from YOF, YF₃, and Y₂O₃ may be deposited using ALD or EBIAD, among other techniques. In some examples, a thickness of the second coating layer 178 deposited using ALD may be about 100 nm to about 500 nm, such as about 100 nm to about 200 nm, about 200 nm to about 300 nm, about 300 nm to about 400 nm, or about 400 nm to about 500 nm. In one example, a thickness of the second coating layer 178 deposited using ALD may be between about 400 nm and 450 nm. In another example, a thickness of the second coating layer 178 deposited using EBIAD may be about 50 nm to about 15 μm, such as about 50 nm to about 1000 nm, about 1 μm to about 5 μm, about 5 μm to about 10 μm, or about 10 μm to about 15 μm. In one example, a thickness of the second coating layer 178 deposited using EBIAD may be between about 10 μm.

In an embodiment, the support body 132 may include a bulk aluminum puck. In such an embodiment, the first coating layer 174 is required to prevent corrosion of the support body 132. As shown in FIG. 1D, the first coating layer 174 is therefore disposed over the outer surface 172 of the base layer 170 via ENP or ALD. Forming the first coating layer 174 from ENP or ALD may ensure conformal coverage over the entire support body 132 on the outer surface 172 of the base layer 170. In one example, the first coating layer 174 may include a nickel and phosphorus alloy formed through ENP and disposed over the entire outer surface 172 of the base layer 170. In such an example, after the first coating layer 174 is deposited via ENP, the second coating layer 178 may be deposited over the first coating layer 174 via ALD or EBIAD. In another example, the first coating layer 174 may include Al₂O₃ disposed over the entire outer surface 172 of the base layer 170 via ALD. In such an example, after the first coating layer 174 is deposited via ALD, the second coating layer 178 may be deposited over the first coating layer 174 via ALD.

In another embodiment, the support body 132 may include material resistant to the process environment such as a bulk nickel or nickel alloy (e.g., Ni100 or Ni200) puck. In such an embodiment, use of the first coating layer 174 may be omitted and the second coating layer 178 may instead be deposited directly on the base layer 170 of the support body 132. In some examples, the second coating layer 178 may be disposed over the outer surface 172 of the base layer 170 via EBIAD or ALD.

In some examples, the second coating layer 178 has a high bulk density which corresponds to low void volume. In some examples, the second coating layer 178 may have a bulk density as a fraction of volumetric mass density of the coating material of about 90% or greater, such as about 95% or greater, such as about 99% or greater, such as about 100%. In some examples, a thickness of the second coating layer 178 may be within a range of about 100 nm to about 40 μm, such as about 100 nm to about 40 μm, such as about 1 μm to about 10 μm, such as about 10 μm to about 20 μm, such as about 20 μm to about 30 μm, such as about 30 μm to about 40 μm, such as about 30 μm. In some examples, the second coating layer 178 may be more durable with the use of a thicker coating (e.g., greater than about 1 μm) compared to the use of a thinner coating (e.g., less than about 1 μm). Thus, in at least some implementations, CVD may be a particularly advantageous process compared to ALD for forming the second coating layer 178. In some examples, a surface roughness average (Ra) of the second coating layer 178 may be within a range of about 5 μin to about 20 μin. In some examples, electrical resistivity of the second coating layer 178 may be about 10⁷ Ohm-cm to about 10⁸ Ohm-cm.

Advantageously, when the substrate-supporting surface 133 of the support body 132 includes a non-metal or reduced-metal coating as shown in FIG. 1D, substrate back side metal contamination is reduced or prevented compared to conventional surface materials of the base layer which can include metal elements such as aluminum oxide (e.g., Al₂O₃). The portion of the support body 132 shown in FIG. 1D corresponds to the substrate-supporting surface 133. In some examples, the second coating layer 178 may be disposed over only the substrate-supporting surface 133. In other words, the second coating layer 178 may extend a radial distance from the center C1 of the support body 132 which is about equal to the first radial distance R1. In some other examples, the second coating layer 178 may be applied to areas outside the substrate-supporting surface 133 over the support body 132. For example, the second coating layer 178 may be applied to an entirety of the upper surface of the support body 132 including the upward-facing surface 141 (shown in FIG. 1B) surrounding the substrate-supporting surface 133. In some examples, the side 143 (e.g., vertical sides) of the support body 132 are free of the second coating layer 178. In some other examples, the second coating layer 178 may be applied around the side 143 (shown in FIG. 1B) of the support body 132. However, portions of the second coating layer 178 disposed over vertical surfaces such as on the side 143 of the support body 132, may have reduced overall coating quality. Therefore, it may be advantageous to avoid coating the side 143. In some examples, the second coating layer 178 may be disposed over an entirety substrate support assembly 106 including corresponding outer surfaces of each of the stem 136 and the support body 132. In some examples, the stem 136 may be free of the second coating layer 178. Application of the second coating layer 178 to the stem 136 may be particularly difficult. Therefore, it may be advantageous to avoid coating the stem 136.

In some examples, the coated substrate support assembly 106 (e.g., shown in FIGS. 1C-1D) may have increased thermal conductivity compared to corresponding uncoated supports. Coating embodiments disclosed herein may be particularly advantageous for improving thermal characteristics of supports formed from aluminum at least in part because uncoated aluminum-based supports provide limited control of substrate temperature compared to more thermally conductive materials.

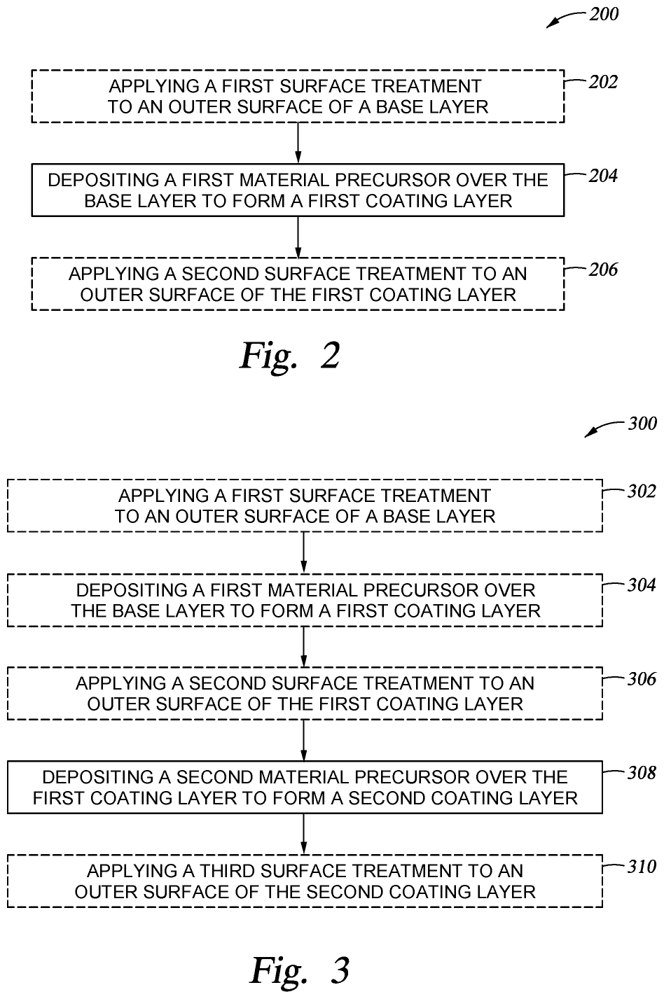

FIG. 2 is a diagram illustrating a method 200 of forming the exemplary surface coating of FIG. 1C, according to certain embodiments. At operation 202, an optional first surface treatment is applied to the outer surface 162 of the base layer 160. In some examples, the first surface treatment may include a cleaning process which removes oxides and trace metals with uniform density. In some examples, the first surface treatment may include O₂ plasma cleaning. In some examples, the cleaning process may include the preclean process described above which may be performed in the processing chamber shown in FIG. 1A. In some other examples, the cleaning process may use a milder process chemistry compared to the preclean process, in which the milder process conditions may be more suitable for cleaning unfinished surfaces (e.g., uncoated surfaces or surfaces which are only coated with a single coating layer) of the substrate support assembly.

At operation 204, a first material precursor is deposited over the base layer 160 to form the first coating layer 164. In some examples, the first material precursor may be deposited using ENP or electrolytic nickel plating, among other processes which are suitable to deposit materials forming the first coating layer 164 as described above. In some examples, the parts of the substrate support assembly 106 to be coated (e.g., the support body 132 and/or stem 136) are submerged in a bath containing the first material precursor.

At operation 206, an optional second surface treatment is applied to the outer surface 166 of the first coating layer 164. In some examples, the second surface treatment may include one or more of the cleaning processes described above with respect to operation 202.

FIG. 3 is a diagram illustrating a method 300 of forming the exemplary surface coating of FIG. 1D, according to certain embodiments. At operation 302, an optional first surface treatment is applied to the outer surface 172 of the base layer 170. In some examples, the first surface treatment may include one or more of the cleaning processes described above with respect to operation 202.

At operation 304, depending on the material of the base layer 170, a first material precursor is optionally deposited over the base layer 170 to form the first coating layer 174. In some examples, the first material precursor may be deposited using ENP or ALD, among other processes which are suitable to deposit materials forming the first coating layer 164 as described above.

At operation 306, an optional second surface treatment is applied to the outer surface 176 of the first coating layer 174. In some examples, the second surface treatment may include one or more of the cleaning processes described above with respect to operation 202. In some examples, the second surface treatment may include reactive ion etching. In some examples, the second surface treatment may include reverse transferred arc plasma cleaning.

At operation 308, a second material precursor is deposited over the optional first coating layer 174 (if formed over the base layer 170), to form the second coating layer 178. In some examples, if the first coating layer 174 is not formed, the second material precursor is deposited directly on the base layer 170. In some examples, the second material precursor may be deposited using air plasma spray, EBIAD, CVD, PECVD, ALD, or PEALD.

At operation 310, an optional third surface treatment is applied to the outer surface 180 of the second coating layer 178. In some examples, the third surface treatment may include one or more of the cleaning processes described above with respect to operation 202.

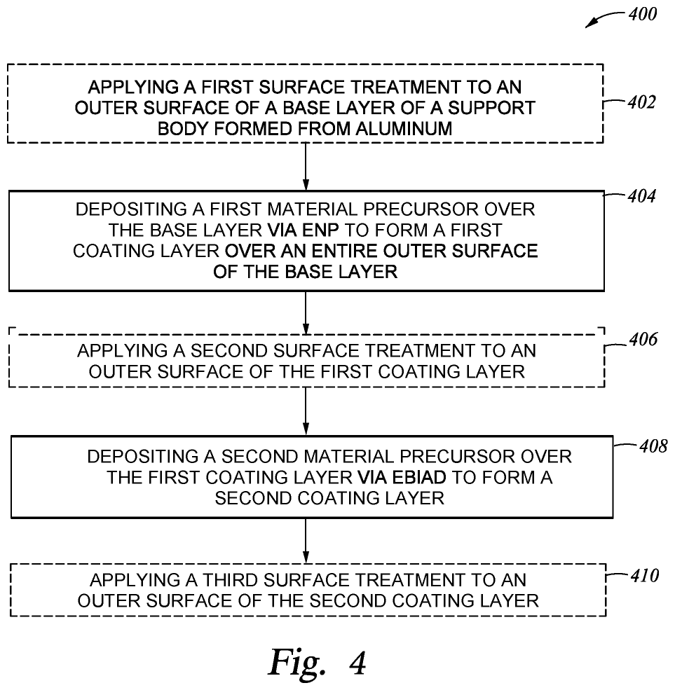

FIG. 4 is a diagram illustrating a method 400 of forming the exemplary surface coating of FIG. 1D via ENP and EBIAD when the support body 132 is formed from a bulk aluminum puck, according to certain embodiments. At operation 402, an optional first surface treatment is applied to the outer surface 172 of the base layer 170. In some examples, the first surface treatment may include one or more of the cleaning processes described above with respect to operation 202.

At operation 404, a first material precursor is deposited over the base layer 170 to form the first coating layer 174. In one embodiment, the first material precursor is a nickel and phosphorus alloy deposited using ENP to form the first coating layer 174. In an embodiment, the ENP first coating layer 174 is formed over an entire surface of the base layer 170.

At operation 406, an optional second surface treatment is applied to the outer surface 176 of the first coating layer 174. In some examples, the second surface treatment may include one or more of the cleaning processes described above with respect to operation 202. In some examples, the second surface treatment may include reactive ion etching. In some examples, the second surface treatment may include reverse transferred arc plasma cleaning.

At operation 408, a second material precursor is deposited over the first coating layer 174 via EBIAD over at least the substrate-supporting surface 133 to form the second coating layer 178. In such an example, the second coating layer 178 may extend from C1 out to at least R1 on the support body 132. The second coating layer 178 may be formed from materials including YOF, YF₃, or Y₂O₃. In another embodiment, the second coating layer 178 may be formed over the entire outer surface 176 of the first coating layer 174.

At operation 410, an optional third surface treatment is applied to the outer surface 180 of the second coating layer 178. In some examples, the third surface treatment may include one or more of the cleaning processes described above with respect to operation 202.

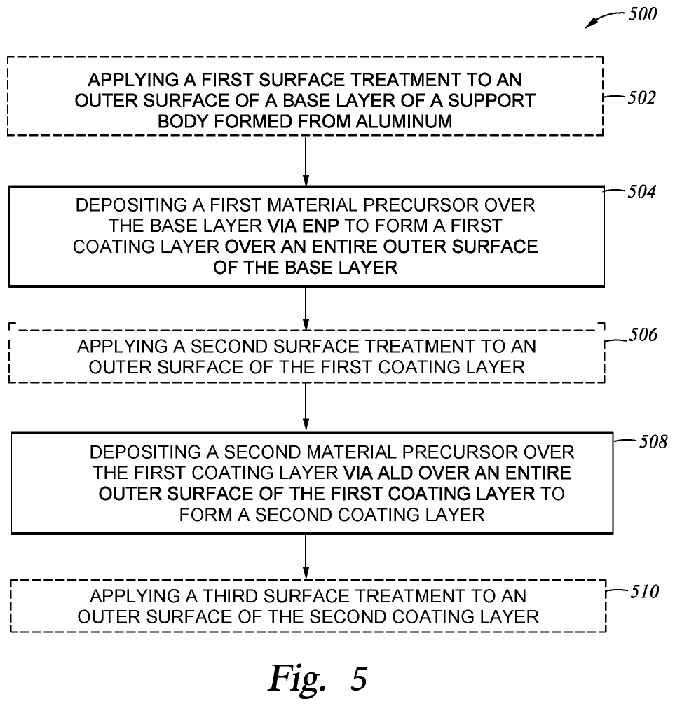

FIG. 5 is a diagram illustrating a method 500 of forming the exemplary surface coating of FIG. 1D via ENP and ALD when the support body 132 is formed from a bulk aluminum puck, according to certain embodiments. At operation 502, an optional first surface treatment is applied to the outer surface 172 of the base layer 170. In some examples, the first surface treatment may include one or more of the cleaning processes described above with respect to operation 202.

At operation 504, a first material precursor is deposited over the base layer 170 to form the first coating layer 174. In one embodiment, the first material precursor is a nickel and phosphorus alloy deposited using ENP to form the first coating layer 174. In an embodiment, the ENP first coating layer 174 is formed over an entire surface of the base layer 170.

At operation 506, an optional second surface treatment is applied to the outer surface 176 of the first coating layer 174. In some examples, the second surface treatment may include one or more of the cleaning processes described above with respect to operation 202. In some examples, the second surface treatment may include reactive ion etching. In some examples, the second surface treatment may include reverse transferred arc plasma cleaning.

At operation 508, a second material precursor is deposited over the entire outer surface 176 of the first coating layer 174 via ALD to form the second coating layer 178. The second coating layer 178 may be formed from materials including YOF, YF₃, or Y₂O₃.

At operation 510, an optional third surface treatment is applied to the outer surface 180 of the second coating layer 178. In some examples, the third surface treatment may include one or more of the cleaning processes described above with respect to operation 202.

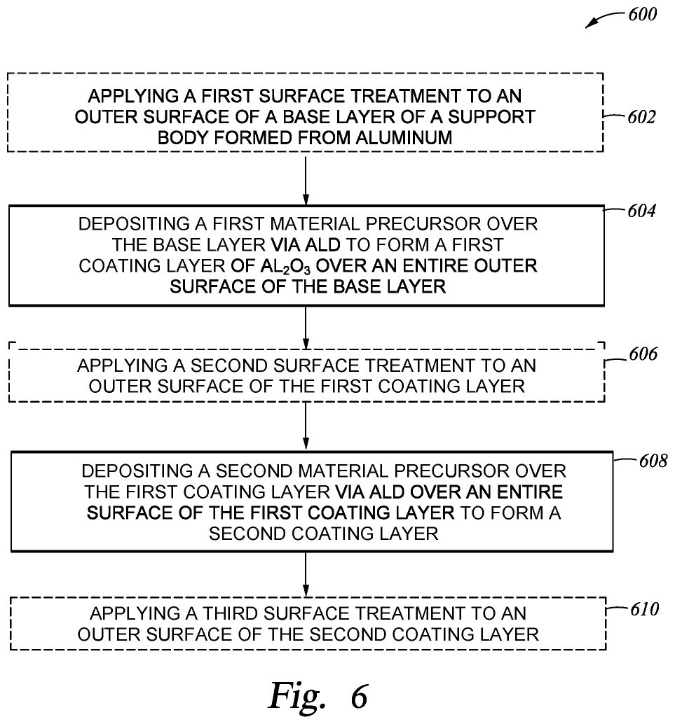

FIG. 6 is a diagram illustrating a method 600 of forming the exemplary surface coating of FIG. 1D via ALD when the support body 132 is formed from a bulk aluminum puck, according to certain embodiments. At operation 602, an optional first surface treatment is applied to the outer surface 172 of the base layer 170. In some examples, the first surface treatment may include one or more of the cleaning processes described above with respect to operation 202.

At operation 604, a first material precursor including Al₂O₃ is deposited over the base layer 170 of the support body 132 to form the first coating layer 174. In an embodiment, the Al₂O₃ precursor is deposited over the entire outer surface 172 of the base layer 170 via ALD to form the first coating layer 174.

At operation 606, an optional second surface treatment is applied to the outer surface 176 of the first coating layer 174. In some examples, the second surface treatment may include one or more of the cleaning processes described above with respect to operation 202. In some examples, the second surface treatment may include reactive ion etching. In some examples, the second surface treatment may include reverse transferred arc plasma cleaning.

At operation 608, a second material precursor is deposited over the first coating layer 174 via ALD to form the second coating layer 178. The second coating layer 178 may be formed from materials including YOF, YF₃, or Y₂O₃.

At operation 610, an optional third surface treatment is applied to the outer surface 180 of the second coating layer 178. In some examples, the third surface treatment may include one or more of the cleaning processes described above with respect to operation 202.

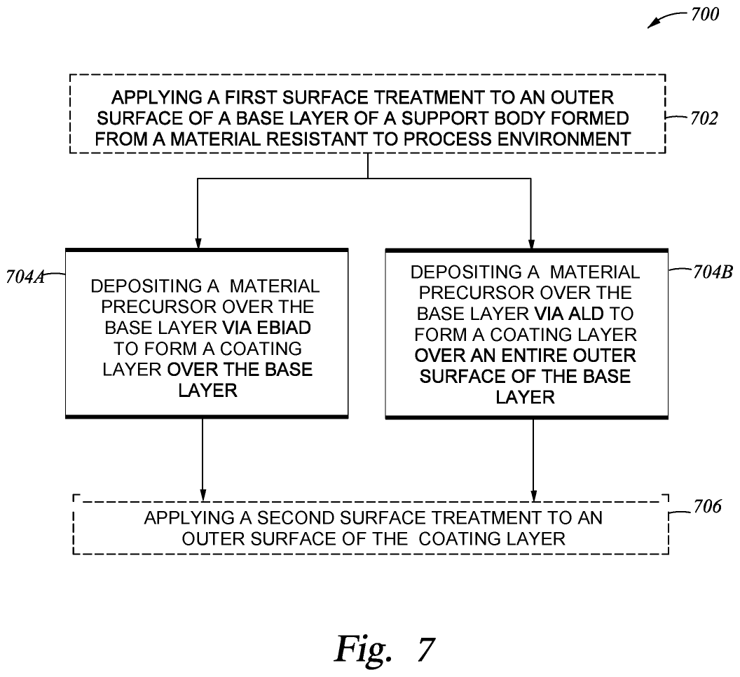

FIG. 7 is a diagram illustrating a method 700 of forming the exemplary surface coating of FIG. 1E via EBIAD or ALD when the support body 132 is formed from a material resistant to the process environment, according to certain embodiments. In an embodiment, the support body 132 may be formed from materials resistant to the process environment in the process chamber including, without limitation, stainless steel, a bulk nickel puck, nickel alloy and the like.

Generally, materials resistant to the process environment in the process chamber include materials that do not generate particles or reaction products when exposed to process gases. In some examples, process gases may include a reactive gas such as a fluorine- or chlorine-containing gas. In some examples, the process gas may further include a vapor. In some examples, the process gas may further include one or more purge gases or carrier gases (e.g., hydrogen, helium, and/or argon). In some examples, the reactive gas may include hydrogen fluoride (e.g., HF), anhydrous hydrogen fluoride (which may be referred to as “AHF”), diatomic fluorine (F₂), nitrogen fluoride (e.g., nitrogen trifluoride (NF₃)), carbon fluoride (e.g., carbon tetrafluoride (CF₄), hexafluoroethane (C₂F₆), trifluoromethane (CHF₃), difluoromethane (CH₂F₂), octofluoropropane (C₃F₈), octofluorocyclobutane (C₄F₈), octofluoro[1-]butane (C₄F₈), octofluoro[2-]butane (C₄F₈), or octofluoroisobutylene (C₄F₈)), sulfur fluoride (e.g., sulfur hexafluoride (SF₆)), ammonia (NH₃), or combinations thereof.

At operation 702, an optional first surface treatment is applied to the outer surface 172 of the base layer 170. In some examples, the first surface treatment may include one or more of the cleaning processes described above with respect to operation 202.

At operation 704A, since the base layer 170 includes material resistant to the process environment, material precursors corresponding to the first coating layer 174 may be omitted and a material precursor is instead deposited over the base layer 170 to form a coating layer 182. The coating layer 182 corresponds to the second coating layer 178 and may therefore include one or more aspects of the second coating layer 178 discussed above. In one embodiment, the material precursor is deposited over the base layer 170 via EBIAD over at least the substrate-supporting surface 133 to form the coating layer 182. The coating layer 182 may be formed from materials including YOF, YF₃, or Y₂O₃. In such an example, the second coating layer 178 may extend from C1 out to at least R1 on the support body 132.

In another embodiment, at operation 704B, the material precursor is alternatively deposited over the base layer 170 via ALD to form the coating layer 182. In such an embodiment, the coating layer 182 is disposed directly over the entire outer surface 172 of the base layer 170. The coating layer 182 may be formed from materials including YOF, YF₃, or Y₂O₃ and may include one or more aspects of the second coating layer 178 discussed above.

At operation 706, an optional second surface treatment is applied to the outer surface 184 of the coating layer 182. In some examples, the second surface treatment may include one or more of the cleaning processes described above with respect to operation 202.

Benefits of the present disclosure include improved coatings for a substrate support assembly of a processing chamber. Certain embodiments provide a two-part surface coating, in contrast to conventional one-part coatings containing metal contaminants. The two-part coating includes an optional first coating which reduces overall surface corrosion of the substrate support assembly and a second coating, free of or containing reduced amounts of metal contaminants, which reduces substrate back side metal contamination.

While the foregoing is directed to embodiments of the present disclosure, other and further embodiments of the disclosure may be devised without departing from the basic scope thereof.

1. A method of forming surface coatings, comprising:
depositing a first material over an outer surface of a support body for a processing chamber to form a first coating layer on the support body, the outer surface of the support body including a top surface, the first material including at least one of a metal-containing material or alloy; and
depositing a second material over at least a portion of the first coating layer disposed over the top surface of the support body, thereby forming a second coating layer, wherein the second material is a non-metal or a reduced-metal material.

2. The method of claim 1, wherein depositing the second material comprises depositing the second material over a substrate support surface on the top surface of the support body, the substrate support surface extending a first radial distance from a center of the support body.

3. The method of claim 1, further comprising depositing the second material over an entirety of the support body.

4. The method of claim 1, wherein depositing the first material comprises performing an ENP process to form the first coating layer, the first coating layer having a thickness in a range of about 10 μm to about 50 μm.

5. The method of claim 1, wherein depositing the second material comprises performing an EBIAD process to form the second coating layer, the second coating layer having a thickness in a range of about 50 nm to about 15 μm.

6. The method of claim 1, wherein depositing the first material comprises performing an ALD process to form the first coating layer, the first coating layer having a thickness in a range of about 5 nm to about 300 nm.

7. The method of claim 1, wherein depositing the second material comprises performing an ALD process to form the second coating layer, the second coating layer having a thickness in a range of about 5 nm to about 500 nm.

8. The method of claim 1, wherein the first coating layer comprises a nickel-phosphorous alloy, and wherein the second coating layer comprises a material selected from the group consisting of YOF, YF₃, and Y₂O₃.

9. The method of claim 1, wherein depositing the first material comprises performing an ALD process to form the first coating layer, the first coating layer comprising Al₂O₃, and wherein depositing the second material comprises performing an ALD process to form the second coating layer, the second coating layer comprising a material selected from the group consisting of YOF, YF₃, and Y₂O₃.

10. A support body for supporting a substrate in a processing chamber, comprising:
a body having an outer surface, the outer surface including a top surface; and
a two-part coating disposed over the outer surface of the body, the two-part coating comprising:
a first coating layer disposed over an entirety of the outer surface of the body, the first coating layer including at least one of a metal-containing material or alloy and comprising a thickness between about 5 nm and about 300 nm; and
a second coating layer disposed over the first coating layer, the second coating layer disposed over at least a portion of the first coating layer disposed over the top surface of the body and extending a radial distance from a center of the body, wherein the second coating layer is a non-metal or reduced-metal coating and comprises a thickness between about 100 nm and about 500 nm.

11. The support body of claim 10, wherein the second coating layer is disposed over an entirety of the first coating layer.

12. The support body of claim 10, wherein the second coating layer is disposed over a substrate contact surface on the top surface of the body.

13. The support body of claim 10, wherein the first coating layer comprises a nickel-phosphorous alloy, and wherein the second coating layer comprises a material selected from the group consisting of yttrium oxyfluoride (YOF), yttrium fluoride (YF₃), and yttrium oxide (Y₂O₃).

14. The support body of claim 10, wherein the first coating layer comprises Al₂O₃, and wherein the second coating layer comprises a material selected from the group consisting of YOF, YF₃, and Y₂O₃.

15. The support body of claim 10, wherein the first coating layer comprises SiO₂, and wherein the second coating layer comprises a material selected from the group consisting of YOF, YF₃, and Y₂O₃.

16. The support body of claim 10, wherein the body comprises aluminum, aluminum oxide, aluminum nitride, or combinations thereof.

17. A system comprising:
a processing chamber configured to clean a substrate, the processing chamber comprising:
a chamber body;
a lid assembly disposed at an upper end of the chamber body, the lid assembly comprising:
a dual channel showerhead having a first set of channels providing fluid communication above and below a plane of the showerhead; and
a second set of channels providing fluid communication with a side port of the chamber body; and
a substrate support assembly at least partially disposed within the chamber body, the substrate support assembly configured to support the substrate in the processing chamber, the substrate support assembly comprising:
a support body having an outer surface, the outer surface including a substrate supporting surface on a top surface of the support body, the substrate supporting surface extending a first radial distance from a center of the support body;
a stem coupled to the support body; and
a coating disposed over the support body, the coating comprising:
a first coating layer disposed over an entirety of the outer surface of the support body, the first coating layer comprising a thickness between about 5 nm and about 300 nm; and
a second coating layer disposed over the first coating layer, the second coating layer extending over at least the substrate supporting surface of the support body and comprising a thickness between about 100 nm and about 500 nm.

18. The system of claim 17, wherein the second coating layer is disposed over an entirety of the first coating layer.

19. The system of claim 17, wherein the first coating layer comprises one of a nickel-phosphorous alloy or Al₂O₃, and wherein the second coating layer comprises a material selected from the group consisting of YOF, YF₃, and Y₂O₃.

20. The system of claim 17, further comprising an epitaxy chamber to grow an epitaxial layer on the substrate after the substrate is cleaned by the processing chamber.
